(19) United States
(12) Patent Application Publication
(10) Pub. No.: US 2015/0249010 A1
(43) Pub. Date: Sep. 3, 2015

(54) SEMICONDUCTOR DEVICE AND METHOD OF MANUFACTURING SAME

(71) Applicant: Kabushiki Kaisha Toshiba, Minato-ku (JP)

(72) Inventor: Hiroshi KUBOTA, Yokkaichi-shi (JP)

(73) Assignee: Kabushiki Kaisha Toshiba, Minato-ku (JP)

(21) Appl. No.: 14/302,716

(22) Filed: Jun. 12, 2014

Related U.S. Application Data
(60) Provisional application No. 61/945,854, filed on Feb. 28, 2014.

(51) Int. Cl. H01L 21/02; H01L 23/00; H01L 27/115; H01L 29/792; H01L 29/66

(52) U.S. Cl. CPC H01L 21/02356; H01L 29/792; H01L 29/66833; H01L 27/11582; H01L 23/562

(57) ABSTRACT

In one embodiment, a semiconductor device includes a substrate, a first inter layer dielectric disposed on the substrate, and a second inter layer dielectric disposed on the first inter layer dielectric. Furthermore, one of the first and second inter layer dielectrics is a first insulator, and the other of the first and second inter layer dielectrics is a second insulator. In addition, the first insulator has a property capable of having a tensile stress in a case where the first insulator is annealed, and the second insulator has a property capable of having a compression stress in a case where the second insulator is annealed.

### CROSS REFERENCE TO RELATED APPLICATION

This application is based upon and claims the benefit of priority from the prior U.S. Provisional Patent Application No. 61/945,854 filed on Feb. 28, 2014, the entire contents of which are incorporated herein by reference.

### FIELD

Embodiments described herein relate to a semiconductor device and a method of manufacturing the same.

### BACKGROUND

In recent years, a structure to form a memory on an inter layer dielectric has been studied. An example of such a memory is a three dimensional stack memory. In a case where such a structure is adopted, annealing of a wafer causes a problem of changing a stress in an inter layer dielectric formed on the wafer so as to cause a warp of the wafer. For example, the inter layer dielectric having a tensile stress before the annealing may have a compression stress after the annealing in some cases, and it is required even in such cases to prevent the wafer from warping. When the wafer is greatly warped, it is hard to form the memory on the inter layer dielectric.

### BRIEF DESCRIPTION OF THE DRAWINGS

FIG. 1 is a cross-sectional view showing a structure of a semiconductor device of a first embodiment; and

FIGS. 2 to 5 are cross-sectional views showing a method of manufacturing the semiconductor device of the first embodiment.

### DETAILED DESCRIPTION

Embodiments will now be explained with reference to the accompanying drawings.

In one embodiment, a semiconductor device includes a substrate, a first inter layer dielectric disposed on the substrate, and a second inter layer dielectric disposed on the first inter layer dielectric. Furthermore, one of the first and second inter layer dielectrics is a first insulator, and the other of the first and second inter layer dielectrics is a second insulator. In addition, the first insulator has a property capable of having a tensile stress in a case where the first insulator is annealed, and the second insulator has a property capable of having a compression stress in a case where the second insulator is annealed.

### First Embodiment

(1) Structure of Semiconductor Device of First Embodiment

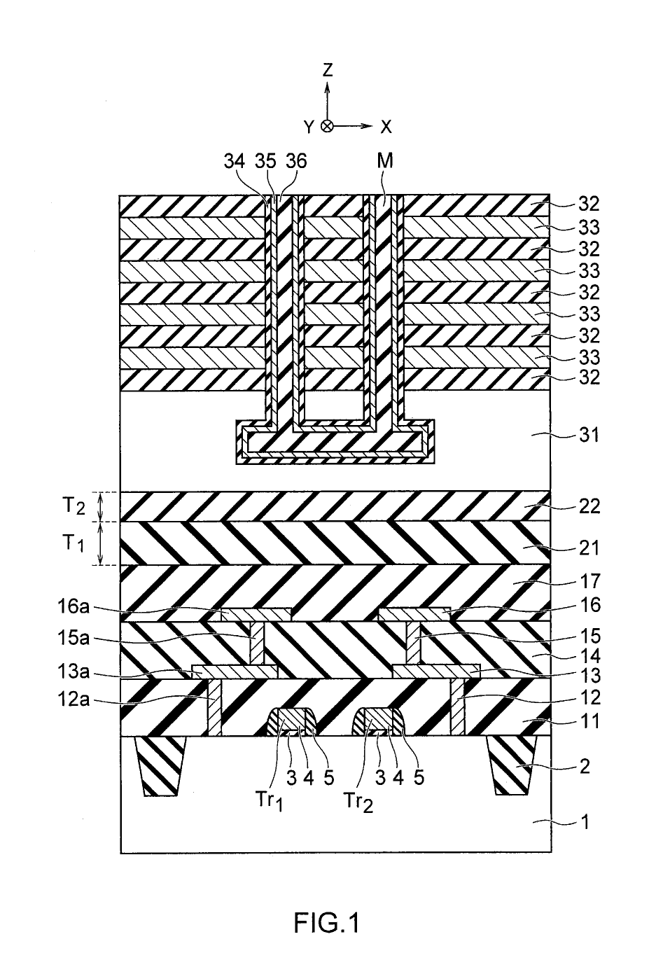

FIG. 1 is a cross-sectional view showing a structure of a semiconductor device of a first embodiment. The semiconductor device of FIG. 1 includes MOS transistors Tr₁ and Tr₂as an example of a transistor, and a three dimensional stack memory M as an example of a memory.

The semiconductor device of FIG. 1 includes a substrate 1, isolation regions 2, gate insulators 3, gate electrodes 4, sidewall insulators 5, inter layer dielectrics 11, 14 and 17 as an example of one or more inter layer dielectrics, plug layers 12 and 15, and interconnect layers 13 and 16.

The semiconductor device of FIG. 1 further includes a first inter layer dielectric 21, a second inter layer dielectric 22, a base semiconductor layer 31, plural insulating layers 32, plural electrode layers 33, a first memory insulator 34 as an example of an insulator, a channel semiconductor layer 35, and a second memory insulator 36.

An example of the substrate 1 is a semiconductor substrate such as a silicon substrate. FIG. 1 shows X and Y directions which are parallel to a surface of the substrate 1 and are perpendicular to each other, and a Z direction perpendicular to the surface of substrate 1. In this specification, the +Z direction is represented as an upward direction, and the −Z direction is represented as a downward direction. For example, a positional relationship between the substrate 1 and the base semiconductor layer 31 is expressed such that the base semiconductor layer 31 is positioned above the substrate 1.

The isolation regions 2 are formed on the surface of the substrate 1. An example of the isolation regions 2 are silicon oxide films.

The gate insulators 3 are formed on the substrate 1. Examples of the gate insulators 3 are silicon oxide films and high-k films. The gate electrodes 4 are formed on the substrate 1 via the gate insulators 3. Examples of the gate electrodes 4 are polysilicon layers and metal layers. The sidewall insulators 5 are formed on side surfaces of the gate electrodes 4. Examples of the sidewall insulators 5 are silicon oxide films and silicon nitride films. The gate insulators 3, the gate electrodes 4 and the sidewall insulators 5 form the MOS transistors Tr₁ and Tr₂.

The inter layer dielectric 11 is formed on the substrate 1 so as to cover the MOS transistors Tr₁ and Tr₂. The plug layer 12 is formed in the inter layer dielectric 11, and includes one or more contact plugs 12a. The interconnect layer 13 is formed on the inter layer dielectric 11, and includes one or more interconnects 13a.

The inter layer dielectric 14 is formed on the inter layer dielectric 11 so as to cover the interconnect layer 13. The plug layer 15 is formed in the inter layer dielectric 14, and includes one or more via plugs 15a. The interconnect layer 16 is formed on the inter layer dielectric 14, and includes one or more interconnects 16a.

The inter layer dielectric 17 is formed on the inter layer dielectric 14 so as to cover the interconnect layer 16.

Examples of the inter layer dielectrics 11, 14 and 17 are silicon oxide films and silicon nitride films. The number of layers of the inter layer dielectrics 11, 14 and 17 may be other than three. An example of the plug layers 12 and 15 is metal layers such as tungsten (W) layers. The number of layers of the plug layers 12 and 15 may be other than two. An example of the interconnect layers 13 and 16 are metal layers such as aluminum (Al) layers or copper (Cu) layers. The number of layers of the interconnect layers 13 and 16 may be other than two. Also, the plug layers 12 and 15 and the interconnect layers 13 and 16 may be formed by a damascene method.

The first inter layer dielectric 21 is formed on the inter layer dielectric 17. The first inter layer dielectric 21 of the present embodiment is a boron phosphorus silicon glass (BPSG) film as an example of a first insulator. The BPSG film has a property of having a tensile stress after it is annealed at a high temperature. In the present embodiment, since the first inter layer dielectric 21 is annealed at 900° C. as described later, the first inter layer dielectric 21 has the tensile stress. A reference character T₁ denotes a thickness of the first inter layer dielectric 21. The thickness T₁ of the present embodiment is 550 nm.

The second inter layer dielectric 22 is formed on the first inter layer dielectric 21. The second inter layer dielectric 22 of the present embodiment is a tetraethyl orthosilicate (TEOS) film as an example of a second insulator. The TEOS film has a property of having a compression stress after it is annealed at a high temperature. In the present embodiment, since the second inter layer dielectric 22 is annealed at 900° C. as described later, the second inter layer dielectric 22 has the compression stress. A reference character T₂ denotes a thickness of the second inter layer dielectric 22. The thickness T₂ of the present embodiment is 100 nm.

The semiconductor device of the present embodiment may adopt a structure that the first inter layer dielectric 21 is the TEOS film and the second inter layer dielectric 22 is the BPSG film.

The base semiconductor layer 31, the plural insulating layers 32, the plural electrode layers 33, the first memory insulator 34, the channel semiconductor layer 35 and the second memory insulator 36 form the three dimensional stack memory M.

The base semiconductor layer 31 is formed on the second inter layer dielectric 22. An example of the base semiconductor layer 31 is a polysilicon layer. The plural insulating layers 32 and the plural electrode layers 33 are alternately stacked on the second inter layer dielectric 22 via the base semiconductor layer 31. An example of the insulating layers 32 is silicon oxide films. An example of the electrode layers 33 is polysilicon layers. Each electrode layer 33 functions as a word line or a select line of the three dimensional stack memory M.

The first memory insulator 34 is formed on a side surface of a hole which penetrates the insulating layers 32 and the electrode layers 33. An example of the first memory insulator 34 is a silicon oxide film. The channel semiconductor layer 35 is formed on the side surface of the hole via the first memory insulator 34. An example of the channel semiconductor layer 35 is a polysilicon layer. The second memory insulator 36 is formed in the hole via the first memory insulator 34 and the channel semiconductor layer 35. An example of the second memory insulator 36 is a silicon oxide film.

(2) Details of Semiconductor Device of First Embodiment

Details of the semiconductor device of the first embodiment will be continuously described below with reference to FIG. 1.

As described above, the first inter layer dielectric 21 of the present embodiment is the BPSG film, and the second inter layer dielectric 22 of the present embodiment is the TEOS film.

It is assumed here that the first inter layer dielectric 21 is a none-doped silicate glass (NSG) film and the second inter layer dielectric 22 is the TEOS film.

When the NSG film is deposited on the substrate 1, the NSG film has a tensile stress. On the other hand, when the TEOS film is deposited on the substrate 1, the TEOS film has a compression stress. Accordingly, if the NGS film and the TEOS film are deposited on the substrate 1, stresses in the NGS film and the TEOS film act to be canceled with each other.

However, if the NSG film is annealed at a high temperature, the stress in the NSG film is changed from the tensile stress to the compression stress. For example, it is revealed that when the NSG film is annealed at 900° C. for 70 minutes, the stress in the NSG film is changed from the tensile stress to the compression stress. In addition, the annealing of the TEOS film at a high temperature causes the compression stress in the TEOS film to increase. For example, it is revealed that when the TEOS film is annealed at 900° C. for 70 minutes, the compression stress in the TEOS film is almost doubled.

In general, if an inter layer dielectric on a wafer has a tensile stress, the wafer warps so as to have a concave shape. On the other hand, if the inter layer dielectric on the wafer has a compression stress, the wafer warps so as to have a convex shape. Accordingly, when the NGS film and the TEOS film are deposited on the substrate 1 and are annealed at a high temperature, the substrate 1 warps so as to have the convex shape due to the compression stresses in the NGS film and the TEOS film.

Therefore, the first inter layer dielectric 21 in the present embodiment is the BPSG film, and the second inter layer dielectric 22 in the present embodiment is the TEOS film.

When the BPSG film is deposited on the substrate 1, the BPSG film has a compression stress. However, if the BPSG film is annealed at a high temperature, a stress in the BPSG film is changed from the compression stress to a tensile stress. For example, it is revealed that when the BPSG film is annealed at 900° C. for 70 minutes, the stress in the BPSG film is changed from the compression stress to the tensile stress.

Accordingly, if the BPSG film and the TEOS film are deposited on the substrate 1 and annealed at a high temperature, the stresses in the BPSG film and the TEOS film act to be canceled with each other. The present embodiment therefore makes it possible to prevent the substrate 1 from warping due to stresses in the first and second inter layer dielectrics 21 and 22 after they are annealed.

In addition, experiments were performed to measure a warp amount of the substrate 1 after the first and second inter layer dielectrics 21 and 22 of the present embodiment are annealed by setting the thicknesses T₁ and T₂ of the first and second inter layer dielectrics 21 and 22 at various values so that a total thickness T₁+T₂ becomes 650 nm. At that time, the annealing temperature was set at 900° C., and the annealing time was set for 70 minutes.

It is desirable that the warp amount of the substrate 1 is within a range of ±0 nm to −20 nm. A positive warp amount means that the substrate 1 warps in a convex shape, and a negative warp amount means that the substrate 1 warps in a concave shape. As the results of the above experiments, it was revealed that when the thickness T₂ of the second inter layer dielectric 22 was about 80 nm to 250 nm, the warp amount became ±0 nm to −20 nm. In addition, it was revealed that when the thickness T₂ of the second inter layer dielectric 22 was 100 nm, the warp amount became a negative value close to ±0 nm. Therefore, the thicknesses T₁ and T₂ of the present embodiment are set at 550 nm and 100 nm, respectively.

If the thicknesses T₁ and T₂ of the first and second inter layer dielectrics 21 and 22 of the present embodiment are set at the same value, the compression stress in the second inter layer dielectric 22 becomes higher than the tensile stress in the first inter layer dielectric 21 after these inter layer dielectrics 21 and 22 are annealed. In this case, the substrate 1 warps in a convex shape. In order to prevent such a warp of the substrate 1, the thickness T₂ of the second inter layer dielectric 22 is set smaller than the thickness T₁ of the first inter layer dielectric 21 in the present embodiment (T₂<T₁).

On the other hand, in a case where the first and second inter layer dielectrics 21 and 22 are respectively insulators other than the BPSG film and the TEOS film, if the thicknesses T₁ and T₂ of the first and second inter layer dielectrics 21 and 22 are set at the same value, a compression stress in the second inter layer dielectric 22 may become lower than a tensile stress in the first inter layer dielectric 21 after these inter layer dielectrics 21 and 22 are annealed. In this case, in order to prevent the substrate 1 from warping in a concave shape, it is desirable to set the thickness T₂ of the second inter layer dielectric 22 larger than the thickness T₁ of the first inter layer dielectric 21 (T₂>T₁).

In this manner, the present embodiment makes it possible, by adjusting a ratio of the thicknesses T₁ and T₂ of the first and second inter layer dielectrics 21 and 22, to effectively prevent the substrate 1 from warping after the first and second inter layer dielectrics 21 and 22 are annealed.

Values of the stresses in the first and second inter layer dielectrics 21 and 22 are changed in response to an annealing temperature of the first and second inter layer dielectrics 21 and 22. Also, the values of the stresses in the first and second inter layer dielectrics 21 and 22 when the semiconductor device is completed depend on the maximum value of the annealing temperature of the first and second inter layer dielectrics 21 and 22. For example, in a case where a process of annealing the first and second inter layer dielectrics 21 and 22 at 780° C. and a process of annealing them at 900° C. are performed, the values of their stresses depend on the annealing temperature of 900° C.

(3) Method of Manufacturing Semiconductor Device of First Embodiment.

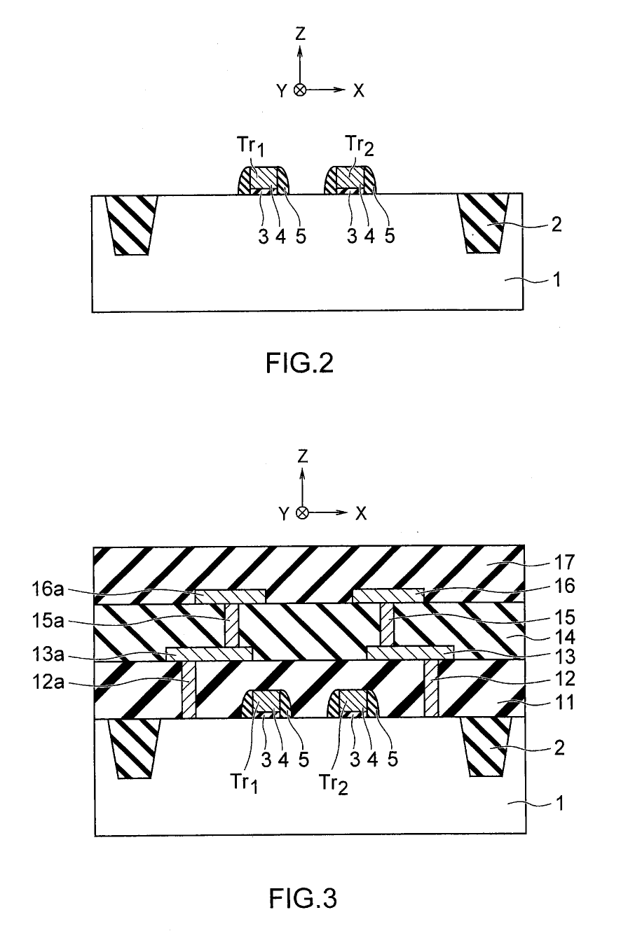

FIGS. 2 to 5 are cross-sectional views showing a method of manufacturing the semiconductor device of the first embodiment.

First, as shown in FIG. 2, the isolation regions 2 are formed on the substrate 1. As shown in FIG. 2, the gate insulators 3, the gate electrodes 4 and the sidewall insulators 5 are then formed on the substrate 1. As a result, the MOS transistors Tr₁ and Tr₂ are formed on the substrate 1.

Next, as shown in FIG. 3, the inter layer dielectric 11, the plug layer 12 and the interconnect layer 13 are formed on the substrate 1. As shown in FIG. 3, the inter layer dielectric 14, the plug layer 15 and the interconnect layer 16 are formed on the inter layer dielectric 11. As shown in FIG. 3, the inter layer dielectric 17 is formed on the inter layer dielectric 14.

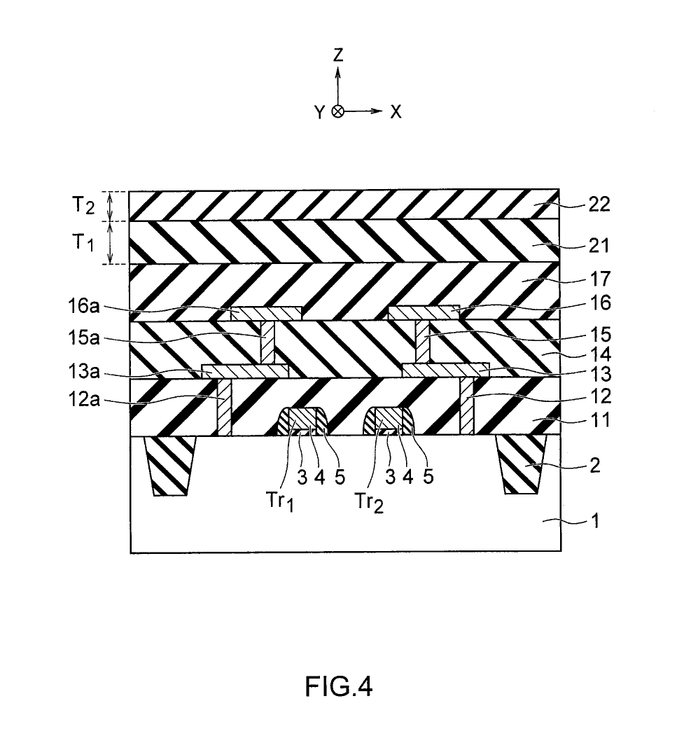

As shown in FIG. 4, the first inter layer dielectric 21 is formed on the inter layer dielectric 14. An example of the first inter layer dielectric 21 is the BPSG film. The first inter layer dielectric 21 is formed, for example, by sheet heat chemical vapor deposition (CVD). As shown in FIG. 4, the inter layer dielectric 22 is formed on the first inter layer dielectric 21. An example of the second inter layer dielectric 22 is the TEOS film. The second inter layer dielectric 22 is formed, for example, by plasma CVD.

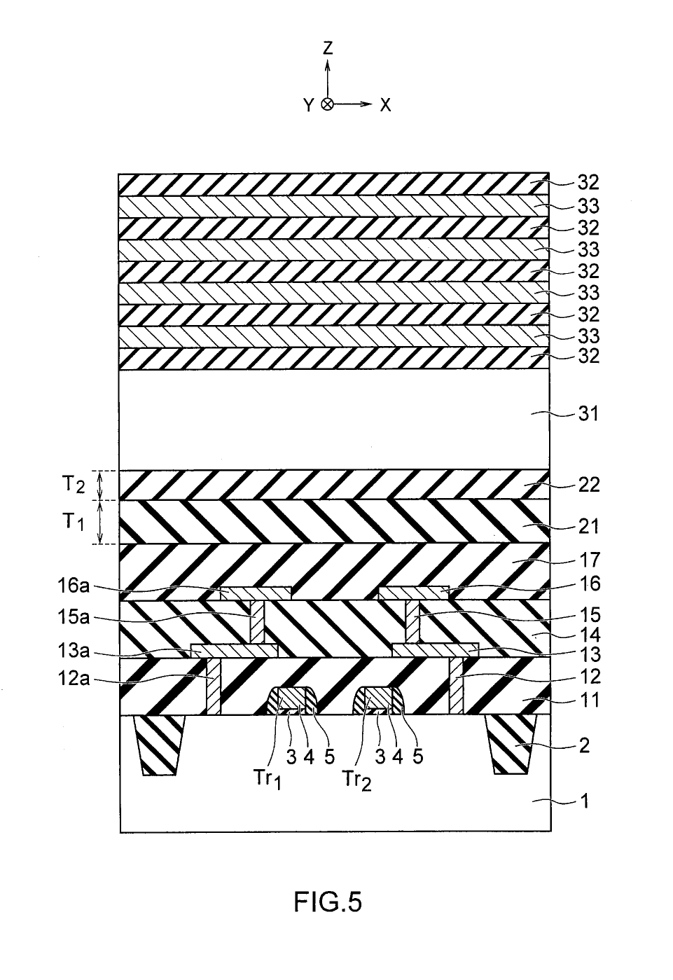

As shown in FIG. 5, the base semiconductor layer 31 is formed on the second inter layer dielectric 22. As shown in FIG. 5, the plural insulating layers 32 and the plural electrode layers 33 are alternately stacked on the base semiconductor layer 31. Next, a hole is formed to penetrate the insulating layers 32 and the electrode layers 33, and the first memory insulator 34, the channel semiconductor layer 35 and the second memory insulator 36 are buried in this hole in order (refer to FIG. 1). As a result, the three dimensional stack memory M is formed on the second inter layer dielectric 22.

After that, various processes for manufacturing the semiconductor device are performed. Also, the substrate 1 is annealed one or more times in a process subsequent to that in FIG. 4. As a result, the first and second inter layer dielectrics 21 and 22 are annealed one or more times. In the present embodiment, the maximum temperature of the annealing is 800° C. or more (for example, 900° C.). This annealing temperature is an example of a predetermined temperature. It is desirable that the annealing at the maximum temperature is performed before the three dimensional stack memory M is formed. The annealing at the maximum temperature results in causing the first inter layer dielectric 21 to have the tensile stress, and the second inter layer dielectric 22 to have the compression stress.

In the present embodiment, a process of annealing the first and second inter layer dielectrics 21 and 22 at 600° C. or more (for example, 780° C.) and a process of annealing them at 800° C. or more (for example, 900° C.) are performed. In such a manner, the semiconductor device of the present embodiment is manufactured.

As described above, one of the first and second inter layer dielectrics 21 and 22 of the present embodiment is a first insulator capable of having a tensile stress in a case where it is annealed, and the other of them is a second insulator capable of having a compression stress in a case where it is annealed. Therefore, the present embodiment makes it possible to prevent the substrate 1 from warping due to the stresses in the first and second inter layer dielectrics 21 and 22 after they are annealed.

The first insulator of the present embodiment may be an insulator other than the BPSG film, if it has a property capable of having a tensile stress in a case where it is annealed. Similarly, the second insulator of the present embodiment may be an insulator other than the TEOS film (for example, an NSG film), if it has a property capable of having a compression stress in a case where it is annealed. The semiconductor device and the method of manufacturing it of the present embodiment can be applied to a memory other than the three dimensional stack memory M.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
a first inter layer dielectric disposed on the substrate; and
a second inter layer dielectric disposed on the first inter layer dielectric,
wherein
one of the first and second inter layer dielectrics is a first insulator,
the other of the first and second inter layer dielectrics is a second insulator,
the first insulator has a property capable of having a tensile stress in a case where the first insulator is annealed, and
the second insulator has a property capable of having a compression stress in a case where the second insulator is annealed.

2. The device of claim 1, wherein the first insulator is a boron phosphorus silicon glass (BPSG) film.

3. The device of claim 1, wherein the second insulator is a tetraethyl orthosilicate (TEOS) film.

4. The device of claim 1, wherein
the first insulator has a property capable of having the tensile stress in a case where the first insulator is annealed at a predetermined temperature, and
the second insulator has a property capable of having the compression stress in a case where the second insulator is annealed at the predetermined temperature.

5. The device of claim 4, wherein the predetermined temperature is 800° C. or more.

6. The device of claim 1, further comprising a memory disposed on the second inter layer dielectric.

7. The device of claim 6, wherein the memory comprises:
plural insulating layers and plural electrode layers alternately stacked on the second inter layer dielectric; and
a channel semiconductor layer disposed on side surfaces of the electrode layers via an insulator.

8. The device of claim 1, further comprising a transistor disposed between the substrate and the first inter layer dielectric.

9. The device of claim 1, further comprising one or more inter layer dielectrics disposed between the substrate and the first inter layer dielectric.

10. The device of claim 1, wherein
a thickness of the second insulator is smaller than a thickness of the first insulator in a case where the compression stress is larger than the tensile stress under assumption that the first and second insulators have the same thickness, and
a thickness of the second insulator is larger than a thickness of the first insulator in a case where the compression stress is smaller than the tensile stress under the assumption that the first and second insulators have the same thickness.

11. A method of manufacturing a semiconductor device, comprising:
forming a first inter layer dielectric on a substrate;
forming a second inter layer dielectric on the first inter layer dielectric; and
annealing the first and second inter layer dielectrics,
wherein
one of the first and second inter layer dielectrics is a first insulator,
the other of the first and second inter layer dielectrics is a second insulator,
the first insulator has a tensile stress after the first and second inter layer dielectrics are annealed, and
the second insulator has a compression stress after the first and second inter layer dielectrics are annealed.

12. The method of claim 11, wherein the first insulator is a boron phosphorus silicon glass (BPSG) film.

13. The method of claim 11, wherein the second insulator is a tetraethyl orthosilicate (TEOS) film.

14. The method of claim 11, wherein
the first insulator has a property capable of having the tensile stress after the first and second inter layer dielectrics are annealed at a predetermined temperature, and
the second insulator has a property capable of having the compression stress after the first and second inter layer dielectrics are annealed at the predetermined temperature.

15. The method of claim 14, wherein the predetermined temperature is 800° C. or more.

16. The method of claim 11, further comprising forming a memory on the second inter layer dielectric.

17. The method of claim 16, wherein the memory comprises:
plural insulating layers and plural electrode layers alternately stacked on the second inter layer dielectric; and
a channel semiconductor layer formed on side surfaces of the electrode layers via an insulator.

18. The method of claim 11, wherein the first inter layer dielectric is formed on the substrate via a transistor.

19. The method of claim 11, wherein the first inter layer dielectric is formed on the substrate via one or more inter layer dielectrics.

20. The method of claim 11, wherein
a thickness of the second insulator is set smaller than a thickness of the first insulator in a case where the compression stress is larger than the tensile stress under assumption that the first and second insulators have the same thickness, and
a thickness of the second insulator is set to larger than a thickness of the first insulator in a case where the compression stress is smaller than the tensile stress under the assumption that the first and second insulators have the same thickness.
